(19) United States
(12) Patent Application Publication
(10) Pub. No.: US 2024/0032336 A1
(43) Pub. Date: Jan. 25, 2024

(54) ARRAY SUBSTRATE, MANUFACTURING METHOD THEREOF, AND ORGANIC LIGHT-EMITTING DIODE DISPLAY PANEL

(71) Applicants: Wuhan China Star Optoelectronics Technology Co., Ltd., Wuhan, Hubei (CN); Wuhan China Star Optoelectronics Semiconductor Display Technology Co., Ltd., Wuhan, Hubei (CN)

(72) Inventor: Linbo KE, Wuhan, Hubei (CN)

(73) Assignees: Wuhan China Star Optoelectronics Technology Co., Ltd., Wuhan, Hubei (CN); Wuhan China Star Optoelectronics Semiconductor Display Technology Co., Ltd., Wuhan, Hubei (CN)

(21) Appl. No.: 17/292,476

(22) PCT Filed: Apr. 20, 2021
(86) PCT No.: PCT/CN2021/088308

§ 371 Date: May 10, 2021

(30) Foreign Application Priority Data
Apr. 7, 2021 (CN) 202110372463.0

(51) Int. Cl. H10K 59/121; H10K 59/12; H10K 59/124

(52) U.S. Cl. CPC H10K 59/1213; H10K 59/1201; H10K 59/124

(57) ABSTRACT

An array substrate, a manufacturing method thereof, and an organic light-emitting diode (OLED) display panel are provided. The array substrate includes a substrate, a first thin-film transistor (TFT), and a second TFT. The first TFT includes a first active layer, a first gate, and a first source/drain electrode. The second TFT includes a second active layer, a second gate, and a second source/drain electrode. Wherein, the first active layer and the second active layer are disposed on a same layer, a material of the first active layer and a material of the second active layer are different, the first gate and the second gate are disposed on a same layer, and the first source/drain electrode and the second source/drain electrode are disposed on a same layer.

### FIELD

The present disclosure relates to the field of display technologies, and more particularly, to an array substrate, a manufacturing method thereof, and an organic light-emitting diode (OLED) display panel.

### BACKGROUND

Unlike conventional liquid crystal displays (LCDs), organic light-emitting diodes (OLEDs) include an organic light-emitting material instead of a backlight. The organic light-emitting material emits light when current flows through. By applying an extremely thin organic material coating layer, OLED display screens can be made thinner and lighter. Furthermore, OLED display screens have wider viewing angles and have significantly lower electrical-energy consumption.

In conventional technologies, a driving backplate of OLEDs is a low-temperature polysilicon thin-film transistor (LTPS-TFT) manufactured by an LTPS process. However, relatively large leakage current of LTPS must result in an increase of power consumption of display devices. By using oxides, such as indium gallium zinc oxide (IGZO) or zinc oxide (ZnO), as an active layer which replaces part of LTPS-TFTs of OLED display devices, possibility of current leakage during a working stage of display devices is reduced because of low leakage current of oxides. This is called a low-temperature polycrystalline oxide (LTPO) technology.

Conventional LTPO display devices include two groups of TFT device structures, namely LTPS and oxides. However, manufacturing processes of the above structures are complex and require many mask plates.

### SUMMARY

An aim of the present disclosure is to provide an array substrate, a manufacturing method thereof, and an OLED display panel to reduce a number of mask plates used in manufacturing processes.

In one aspect, the present disclosure provides an array substrate, including:
a substrate;
a first thin-film transistor (TFT) disposed above the substrate and comprising a first active layer, a first gate, and a first source/drain electrode; and
a second TFT disposed above the substrate and comprising a second active layer, a second gate, and a second source/drain electrode;
wherein the first active layer and the second active layer are disposed on a same layer, a material of the first active layer and a material of the second active layer are different, the first gate and the second gate are disposed on a same layer, and the first source/drain electrode and the second source/drain electrode are disposed on a same layer.

Furthermore, the array substrate comprises a shielding layer disposed above the substrate and disposed below the first TFT and the second TFT, and a buffer layer disposed above the substrate and covering the shielding layer. Wherein, the shielding layer is electrically connected to the first source/drain electrode and/or the second source/drain electrode by a first conductive pillar.

Furthermore, the substrate comprises a stacked layer comprising an organic layer and an inorganic layer.

Furthermore, the material of the first active layer is low-temperature polycrystalline silicon, and the material of the second active layer is an oxide.

Furthermore, the first TFT further comprises a first gate insulating layer disposed above the buffer layer, a second gate insulating layer disposed above the first gate insulating layer, and a third gate disposed above the second gate insulating layer.

Furthermore, the first source/drain electrode is connected to the second source/drain electrode, and the first conductive pillar is disposed at a connecting part between the first TFT and the second TFT.

Furthermore, the array substrate further comprises a passivation layer covering the first source/drain electrode and the second source/drain electrode, a planarization layer disposed above the passivation layer, and an anode layer and a pixel-defining layer disposed above the planarization layer, wherein the anode layer is electrically connected to the first source/drain electrode and/or the second source/drain electrode by a second conductive pillar.

In another aspect, the present provides a method of manufacturing an array substrate, including following steps:
providing a substrate;
forming a first thin-film transistor (TFT) comprising a first active layer, a first gate, and a first source/drain electrode above the substrate, and forming a second TFT comprising a second active layer, a second gate, and a second source/drain electrode above the substrate, wherein the first active layer and the second active layer are disposed on a same layer, a material of the first active layer and a material of the second active layer are different, the first gate and the second gate are formed by a single patterning process, and the first source/drain electrode and the second source/drain electrode are formed by a single process.

Furthermore, the method includes following steps:
forming a shielding layer above the substrate and below the first TFT and the second TFT, wherein the shielding layer is electrically connected to the first source/drain electrode and/or the second source/drain electrode by a first conductive pillar; and
forming a buffer layer above the substrate and covering the shielding layer.

Furthermore, the substrate comprises a stacked layer comprising an organic layer and an inorganic layer.

Furthermore, the material of the first active layer is low-temperature polycrystalline silicon, and the material of the second active layer is an oxide.

Furthermore, the material of the first active layer is low-temperature polycrystalline silicon, and the material of the second active layer is an oxide.

Furthermore, the first TFT further comprises a first gate insulating layer disposed above the buffer layer, a second gate insulating layer disposed above the first gate insulating layer, and a third gate disposed above the second gate insulating layer.

Furthermore, the first source/drain electrode is connected to the second source/drain electrode, and the first conductive pillar is disposed at a connecting part between the first TFT and the second TFT.

Furthermore, the array substrate further comprises a passivation layer covering the first source/drain electrode and the second source/drain electrode, a planarization layer disposed above the passivation layer, and an anode layer and a pixel-defining layer disposed above the planarization layer, wherein the anode layer is electrically connected to the first source/drain electrode and/or the second source/drain electrode by a second conductive pillar.

In yet another aspect, the present disclosure provides an OLED display panel, including:
the above-mentioned array substrate;
an organic light-emitting layer disposed above the array substrate;
a cathode layer disposed above the organic light-emitting layer;
a thin-film encapsulation layer disposed above the cathode layer;
a touch control layer disposed above the thin-film encapsulation layer;
a polarizer disposed above the touch control layer; and
a cover plate disposed above the polarizer.

Furthermore, the array substrate comprises a shielding layer disposed above the substrate and disposed below the first TFT and the second TFT, and a buffer layer disposed above the substrate and covering the shielding layer. Wherein, the shielding layer is electrically connected to the first source/drain electrode and/or the second source/drain electrode by a first conductive pillar.

Furthermore, the substrate comprises a stacked layer comprising an organic layer and an inorganic layer.

Furthermore, the material of the first active layer is low-temperature polycrystalline silicon, and the material of the second active layer is an oxide.

Furthermore, the first TFT further comprises a first gate insulating layer disposed above the buffer layer, a second gate insulating layer disposed above the first gate insulating layer, and a third gate disposed above the second gate insulating layer.

Furthermore, the first source/drain electrode is connected to the second source/drain electrode, and the first conductive pillar is disposed at a connecting part between the first TFT and the second TFT.

Regarding the beneficial effects: the present disclosure provides an array substrate, a manufacturing method thereof, and an OLED display panel. The array substrate includes a substrate, a first thin-film transistor (TFT), and a second TFT. The first TFT includes a first active layer, a first gate, and a first source/drain electrode. The second TFT includes a second active layer, a second gate, and a second source/drain electrode. Wherein, the first active layer and the second active layer are disposed on a same layer, a material of the first active layer and a material of the second active layer are different, the first gate and the second gate are disposed on a same layer, and the first source/drain electrode and the second source/drain electrode are disposed on a same layer. Therefore, only four mask plates are required when manufacturing the first TFT and the second TFT of the active layer having different materials. Thus, a number of the mask plates used in manufacturing processes is significantly reduced.

### DESCRIPTION OF DRAWINGS

Technical solutions and beneficial effects of the present disclosure are illustrated below in detail in conjunction with drawings and specific embodiments.

FIG. 1 is a structural schematic view showing an array substrate provided by a first embodiment of the present disclosure.

FIG. 2 is a structural schematic view showing an array substrate provided by a second embodiment of the present disclosure.

FIG. 3 is a structural schematic view showing an array substrate provided by a variation of the second embodiment.

FIG. 4 is a structural schematic view showing an array substrate provided by a third embodiment of the present disclosure.

FIG. 5 is a schematic flowchart showing a method of manufacturing an array substrate provided by a fourth embodiment of the present disclosure.

FIGS. 6a to 6g are structural schematic views showing the array substrate provided by the fourth embodiment during manufacturing processes.

FIG. 7 is a structural schematic view showing an OLED display panel provided by a fifth embodiment of the present disclosure.

### DETAILED DESCRIPTION

Hereinafter a preferred embodiment of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

In the description of the present disclosure, unless specified or limited otherwise, it should be noted that a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

Illustration below provides many different embodiments or examples to demonstrate different structures of the present disclosure. In order to simplify the disclosure of the present disclosure, components and settings of specific examples are described below. Of course, they are only examples and are not intended to limit the present disclosure. Furthermore, reference numbers and/or letters may be repeated in different examples of the present disclosure. Such repetitions are for simplification and clearness, which per se do not indicate the relations of the discussed embodiments and/or settings. Moreover, the present disclosure provides examples of various specific processes and materials, but the applicability of other processes and/or application of other materials may be appreciated by a person skilled in the art.

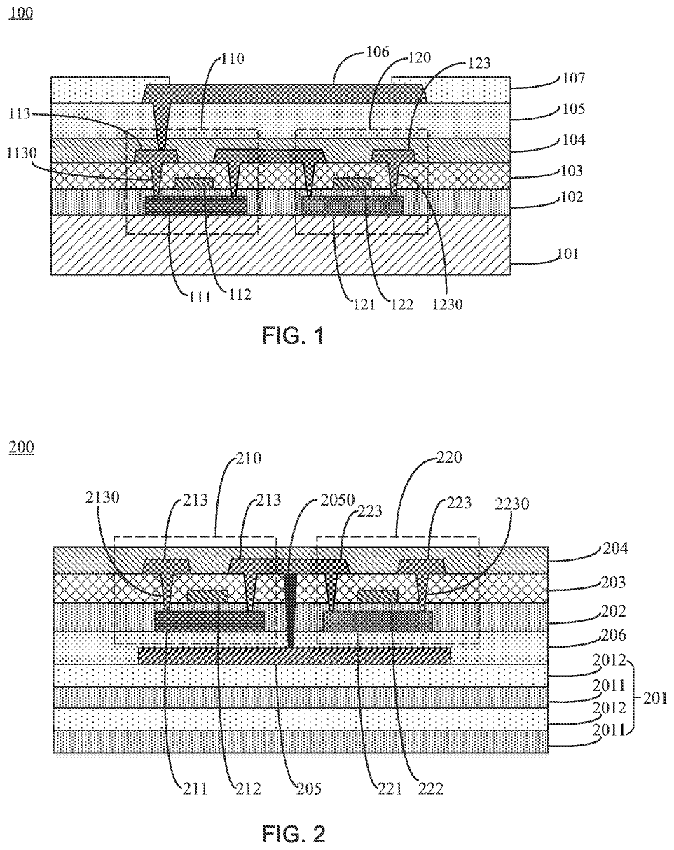

Please refer to FIG. 1. FIG. 1 is a structural schematic view showing an array substrate provided by a first embodiment of the present disclosure. An array substrate 100 includes a substrate 101, and a first thin-film transistor (TFT) 110 and a second TFT 120 disposed above the substrate 101. The substrate 101 may be made of a flexible polyimide (PI) material. The first TFT 110 includes a first active layer 111 disposed above the substrate 101, a first gate insulating layer 102 disposed above the substrate 101 and covering the first active layer 111, a first gate 112 disposed above the first gate insulating layer 102, a medium layer 103 disposed above the first gate insulating layer 102 and covering the first gate 112, and a first source/drain electrode 113 disposed above the medium layer 103 and electrically connected to the first active layer 111 by a first conductive point 1130. The second TFT 120 is similar to the first TFT 110 and includes a second active layer 121 disposed above the substrate 101, the first gate insulating layer 102 disposed above the substrate and covering the second active layer 121, a second gate 122 disposed above the first gate insulating layer 102, the medium layer 103 disposed above the first gate insulating layer 102 and covering the second gate 122, and a second source/drain electrode 123 disposed above the medium layer 103 and electrically connected to the second active layer 121 by a second conductive point 1230. In the present embodiment, the first source/drain electrode 113 is connected to the second source/drain electrode 123. Optionally, the first source/drain electrode 113 may not be connected to the second source/drain electrode 123 due to different circuit designs.

Wherein, the first active layer 111 and the second active layer 121 are disposed on a same layer and have different materials. A material of the first active layer 111 may be low-temperature polysilicon (LTPS). A material of the second active layer 121 may be oxides such as indium gallium zinc oxide (IGZO) or zinc oxide (ZnO). The first TFT 110 may be a driving TFT and the second TFT 120 may be a switch TFT, which are determined by material characteristics of the active layer. In the present embodiment, the first gate 112 and the second gate 122 are disposed on a same layer, and the first source/drain electrode 113 and the second source/drain electrode 123 are disposed on a same layer. Since the material of the first active layer 111 and the material of the second active layer 121 are different, two mask plates are required during manufacturing processes. In addition, forming the gate and the source/drain electrode respectively requires one mask plate. Therefore, manufacturing the first TFT 110 and the second TFT 120 requires four mask plates in total.

In the present embodiment, the array substrate 100 further includes a passivation layer 104 disposed above the medium layer 103 and covering the first source/drain electrode 113 and the second source/drain electrode 123, a planarization layer 105 disposed above the passivation layer 104, and an anode layer 106 and a pixel-defining layer 107 disposed above the planarization layer 105. The pixel-defining layer 107 is disposed above the anode layer 106 and exposes the anode layer 106.

In conventional technologies, active layers of two TFTs are not disposed on a same layer, resulting in source/drain electrodes of the two TFTs not disposed on a same layer. Therefore, more mask plates are required during manufacturing processes. Compared with conventional technologies, in the array substrate 100 provided by the present embodiment, only four mask plates are required during manufacturing processes of two TFTs. Therefore, a number of mask plates required during manufacturing processes is significantly reduced. As such, not only manufacturing processes but also costs are reduced.

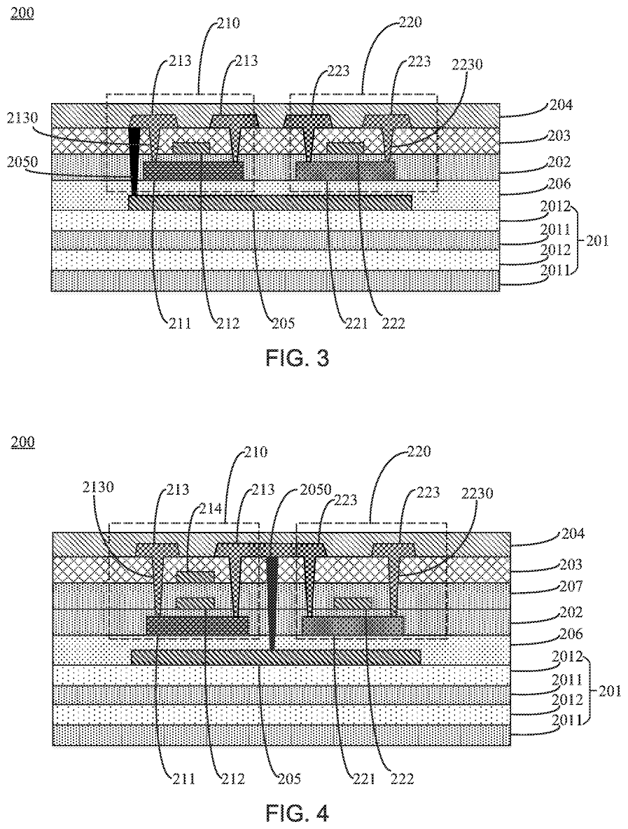

Please refer to FIG. 2, FIG. 2 is a structural schematic view showing an array substrate provided by a second embodiment of the present disclosure. An array substrate 200 includes a substrate 201, a shielding layer 205 disposed above the substrate 201, a buffer layer 206 disposed above the substrate 101 and covering the shielding layer 205, and a first TFT 210 and a second TFT 220 disposed above the buffer layer 206. Wherein, the first TFT 210 includes a first active layer 211, a first gate insulating layer 202 covering the first active layer 211, a first gate 212 disposed above the first gate insulating layer 202, a medium layer 203 covering the first gate 212, a first source/drain electrode 213 disposed above the medium layer 203, and a passivation layer 204 covering the first source/drain electrode 213. The second TFT 220 includes the first active layer 221, the first gate insulating layer 202, a second gate layer 222, the medium layer 203, a second source/drain electrode 223, and the passivation layer 204. Wherein, the first source/drain electrode 213 is electrically connected to the first active layer 211 by a first conductive point 2130, and the second source/drain electrode 223 is electrically connected to the second active layer 221 by a second conductive point 2230. Wherein, the first conductive point 2130 and the second conductive point 2230 vertically penetrates the medium layer 203 and part of the first gate insulating layer 202.

Wherein, a material of the shielding layer 205 is metal. The shielding layer 205 is electrically connected to the source/drain electrodes disposed thereabove by a first conductive pillar 2050. The first conductive pillar 2050 vertically penetrates the medium layer 203, the first gate insulating layer 202, and part of the buffer layer 206. A bottom end of the first conductive pillar 2050 is in contact with the shielding layer 205, and a top end of the first conductive pillar 2050 is in contact with the source/drain electrode. When the first source/drain electrode 213 is connected to the second source/drain electrode 223, the top end of the first conductive pillar 2050 may be in contact with the first source/drain electrode 213 and the second source/drain electrode 223. Furthermore, the first conductive pillar 2050 may just be disposed between a connecting point between the first source/drain electrode 213 and the second source/drain electrode 223. When the first source/drain electrode 213 is not connected to the second source/drain electrode 223, the top end of the first conductive pillar 2050 may be in contact with any one of the source/drain electrodes.

In the present embodiment, the substrate 201 includes a stacked layer including an organic layer 2011 and an inorganic layer 2012. The organic layer 2011 may include polyimide (PI), thereby realizing a flexible substrate. The inorganic layer 2012 may include an inorganic material having good water-blocking performance. An aim of disposing the stacked layer on the substrate 201 is to test performance in sequential processes. According to researches, the organic layer 2011, the inorganic layer 2012, the buffer layer 206, the first gate insulating layer 202, and the medium layer 203 include certain moving electric charges. Driven by a current of TFT devices, moving electric charges will badly affect the TFT devices, deteriorate electrical performance of the TFT devices, and badly affect reliability and optical evaluation of the TFT devices. In the array substrate 200 provided by the present embodiment, moving electric charges may be attracted by the shielding layer 205 and may be introduced outside by the source/drain electrodes. Since the shielding layer 205 is disposed below the TFTs, it can block moving electric charges at a bottom side or a lateral surface of TFTs. Therefore, reliability of the TFTs can be significantly improved without affecting electrical performance of the TFTs. As such, an improved flexible display screen can be realized.

In the present embodiment, the shielding layer 205 is mainly configured to prevent moving electrical charges from affecting the active layer. Therefore, the shielding layer 205 is near the first active layer 211 and the second active layer 221. In some embodiments, to prevent moving electrical charges from affecting other structures, the shielding layer 205 may also be disposed on other positions.

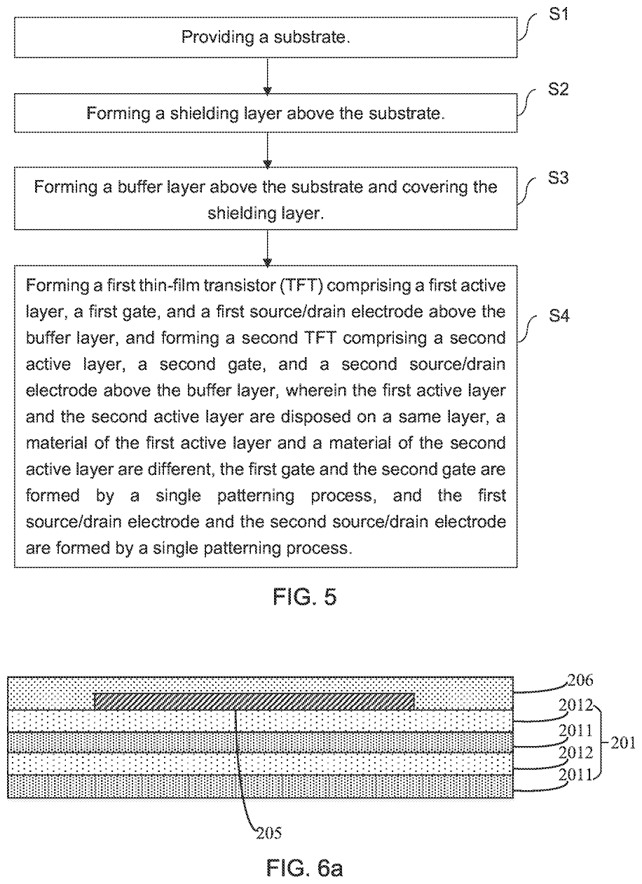

Please refer to FIG. 3. FIG. 3 is a structural schematic view showing an array substrate provided by a variation of the second embodiment. In the variation and the second embodiment, identical structures have same reference numbers. A difference between the variation and the second embodiment is a position of the first conductive pillar 2050. In the present embodiment, the first source/drain electrode 213 is not connected to the second source/drain electrode 223. The first conductive pillar 2050 may be in contact with any one of four source/drain electrodes. Optionally, the first conductive pillar 2050 may be disposed on a left side of the shielding layer 205 and may be connected to the first source/drain electrode 213 at the leftmost. Alternatively, the first conductive pillar 2050 may be disposed on a right side of the shielding layer 205 and may be connected to the second source/drain electrode 223 at the rightmost. Moving electric charges in the organic layer 2011 and the inorganic layer 2022 are attracted by the shielding layer 205. Then, the moving electric charges are introduced to the source/drain electrodes by the first conductive pillar 2050. Finally, the moving electric charges are introduced outside by the source/drain electrodes. Therefore, the array substrate may be prevented from being affected by moving electric charges at a bottom of the shielding layer 205. Moving electric charges at a top of the shield layer 205 may also be blocked to a certain degree, which depends on a voltage applied to the shielding layer 205 and a capability to attract electric charges.

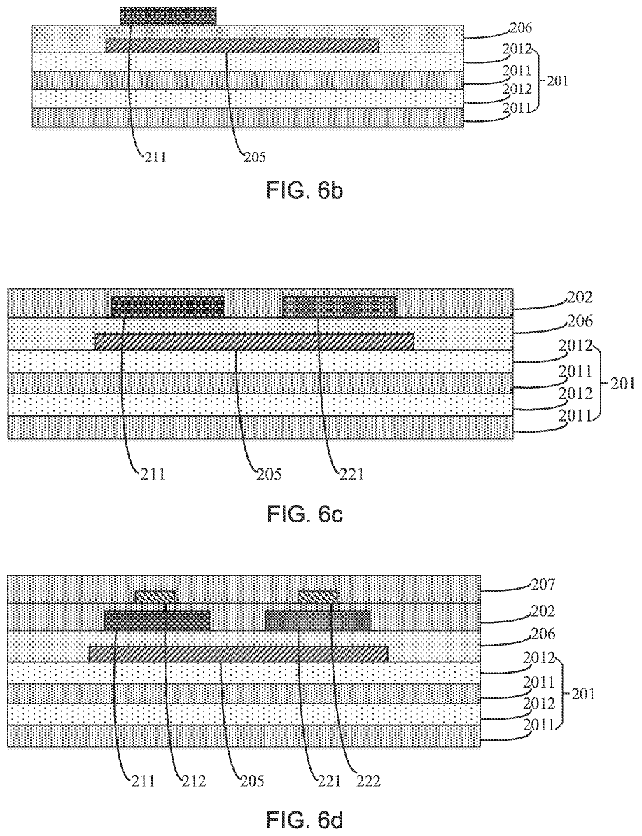

Please refer to FIG. 4. FIG. 4 is a structural schematic view showing an array substrate provided by a third embodiment. For ease of illustration, identical structures in the third embodiment and the second embodiment have same reference numbers. A difference between the third embodiment and the second embodiment is: in the third embodiment, the first TFT 210 has a double-gate structure and further includes a third gate 214. Specifically, the first TFT 210 includes the first active layer 211 disposed above the buffer layer 206, the first gate insulating layer 202 disposed above the buffer layer 206 and covering the first active layer 211, the first gate 212 disposed above the first gate insulating layer 202, the second gate insulating layer 207 disposed above the first gate insulating layer 202 and covering the first gate 212, a third gate 214 disposed above the second gate insulating layer 207, the medium layer 203 disposed above the second gate insulating layer 207 and covering the third gate 214, and the first source/drain electrode 213 disposed above the medium layer 203. Wherein, the first source/drain electrode 213 is electrically connected to two ends of the first active layer 211 by the first conductive point 2130.

In the present embodiment, the first TFT 210 has a double-gate structure, thereby improving stability of the device. Optionally, the third gate 214 may be disposed below the first active layer 211. In some embodiments, the second TFT 220 may also have a double-gate structure.

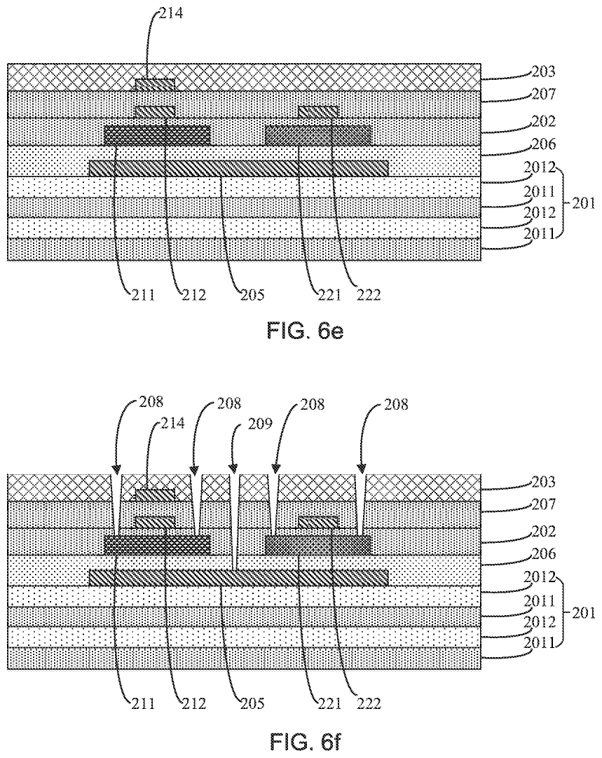

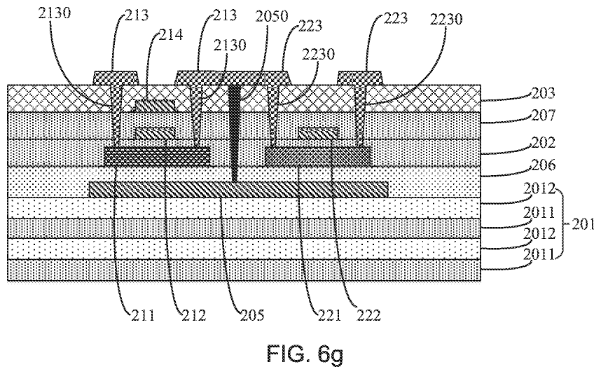

Please refer to FIG. 5. FIG. 5 is a schematic flowchart showing a method of manufacturing an array substrate provided by a fourth embodiment of the present disclosure. Please refer to FIGS. 6a to 6g. FIGS. 6a to 6g are structural schematic views showing the array substrate provided by the fourth embodiment during manufacturing processes. The array substrate 200 of the third embodiment may be manufactured by the method. Therefore, please also refer to FIG. 4. The method of manufacturing the array substrate includes following steps S1 to S4.

First, please refer to the steps S1 to S3 and FIG. 6a.

The step S1: providing a substrate 201.

The step S2: forming a shielding layer 205 above the substrate 201.

The step S3: forming a buffer layer 206 above the substrate 201 and covering the shielding layer 205.

In one embodiment, a stacked-layer substrate sequentially having an organic layer 2011, an inorganic layer 1012, an organic layer 2011, and an inorganic layer 2012 is formed. The organic layer 2011 includes PI, and the inorganic layer 1012 includes an inorganic material having good water-blocking performance. Then, a metal material is deposited on the substrate 201, the shielding layer 205 is formed by a patterning process with a mask plate, and the buffer layer 206 is formed by chemical vapor deposition (CVD), wherein the formed structure is as shown in FIG. 6a.

Please refer to step S4 in FIG. 5 and FIGS. 6b to 6g.

The step S4: forming a first TFT 210 comprising a first active layer 211, a first gate 212, and a first source/drain electrode 213 above the buffer layer 206, and forming a second TFT 220 comprising a second active layer 221, a second gate 222, and a second source/drain electrode 223 above the buffer layer 206, wherein the first active layer 211 and the second active layer 221 are disposed on a same layer, a material of the first active layer 211 and a material of the second active layer 221 are different, the first gate 212 and the second gate 222 are formed by a single patterning process, and the first source/drain electrode 213 and the second source/drain electrode 223 are formed by a single patterning process.

Specifically, the step S4 includes following steps: 1) depositing LTPS on the buffer layer 206 and performing a patterning process to form the first active layer 211, wherein the formed structure is as shown in FIG. 6b. 2) Depositing IGZO on the buffer layer 206, performing a patterning process to form the second active layer 221, and forming a first gate insulating layer 202 covering the first active layer 211 and the second active layer 221, wherein the formed structure is as shown in FIG. 6c. 3) Depositing a gate material on the first gate insulating layer 202, simultaneously forming a first gate 212 and a second gate 222 by a patterning process with a mask plate, and forming a second gate insulating layer 207 covering the first gate 212 and the second gate 222, wherein the formed structure is as shown in FIG. 6d. 4) Depositing a gate material on the second gate insulating layer 207, forming a third gate 214 by a patterning process with a mask plate, and forming a second medium layer 203 covering the third gate 214, wherein the formed structure is as shown in FIG. 6e. 5) Respectively defining a plurality of holes on the medium layer 203, the second gate insulating layer 207, and part of the first gate insulating layer 202 with laser, thereby forming a plurality of first through-holes 208 defined at two ends of the first active layer 221 and two ends of the second active layer 221, a bottom end of the first through-holes 208 is in contact with the first active layer 211 and the second active layer 221. Also, defining a hole on a middle portion of the shielding layer 205, the medium layer 203, the second gate insulating layer 207, the first gate insulating layer 202, and part of the buffer layer 206 with laser, thereby forming a second through-hole 209, wherein a bottom end of the second through-hole 209 is in contact with the shielding layer 205. The first through-holes 208 and the second through-hole 209 are formed in different steps of a single etching process. After the first through-holes 208 are formed, a position where the second through-hole 209 is to be formed is continuously etched until it reaches the shielding layer 205, thereby forming the second through-hole 209, wherein the formed structure is as shown in FIG. 6f. 6) Depositing a conductive material in the first through-holes 208 and the second through-hole 209 to cover the medium layer 203, and performing a patterning process with a mask plate to form a first conductive point 2130, a first source/drain electrode 213, a second conductive point 2230, a second source/drain electrode 223, and a first conductive pillar 2050, wherein the formed structure is as shown in FIG. 6g. Wherein, a material of the first conductive pillar 2050 and materials of the first conductive point 2130 and the second conductive point 2230 may be different. 7) Forming a passivation layer 204 covering the first source/drain electrode 213 and the second source/drain electrode 223, wherein the formed structure is as shown in FIG. 4.

In the method of manufacturing the array substrate 200 provided by the present embodiment, when the first TFT 210 and the second TFT 220 have a single-gate structure (without the third gate 214), forming the first active layer 211 and the second active layer 221 requires performing two patterning processes with two mask plates, forming the first gate 212 and the second gate 222 requires performing one patterning process with one mask plate, and forming the first source/drain electrode 213 and the second source/drain electrode 223 requires performing one patterning process with one mask plate. Therefore, forming the first TFT 210 and the second TFT 220 as shown in FIG. 2 requires performing only four patterning processes with four mask plates in total. Compared with convention technologies which have the first TFT 210 and the second TFT 221 disposed on different layers, a number of mask plates and a number of patterning processes required to form two TFTs having different active layer materials provided by the present embodiment are significantly reduced. When the first TFT 210 has a double-gate structure as shown in FIG. 4, forming two TFTs requires performing five patterning processes with five mask plates in total.

In the manufacturing method provided by the present embodiment, an additional mask plate and an additional patterning process is added to form the shielding layer 205 disposed below the first TFT 210 and the second TFT 220, thereby effectively preventing the TFTs from being affected by moving electric charges in the organic layer 2011 and the inorganic layer 2012. Therefore, reliability of the TFTs can be ensured without affecting electrical performance of the device. As such, a flexible display screen having improved performance can be realized.

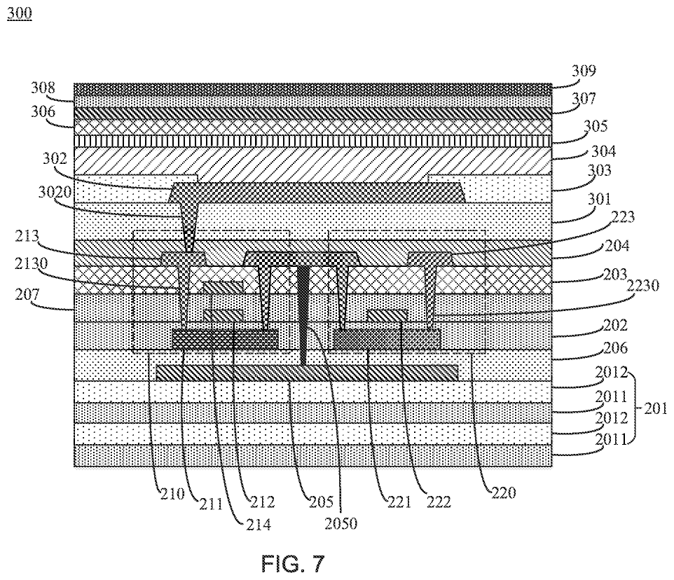

Please refer to FIG. 7. FIG. 7 is a structural schematic view showing an OLED display panel provided by a fifth embodiment of the present disclosure. In an OLED display panel 300 and the array substrate 200, identical structures have same reference numbers. The array substrate further includes a planarization 301 disposed above the passivation layer 204, and an anode layer 302 and a pixel-defining layer 303 disposed above the planarization layer 301. The pixel-defining layer 303 is disposed above the anode layer 302 and exposes the anode layer 302. Wherein, the anode layer 302 is electrically connected to the first source/drain electrode 213 and/or the second source/drain electrode 223 by a second conductive pillar 3020. The second conductive pillar 3020 vertically penetrates the planarization layer 301 and part of the passivation layer 204. The OLED display panel 300 further includes an organic light-emitting layer 304 disposed above the array substrate (the anode layer 302 and the pixel-defining layer 303), a cathode layer 305 disposed above the organic light-emitting layer 304, an encapsulation layer 306 disposed above the cathode layer 305, a touch control layer 307 disposed above the encapsulation layer 306, a polarizer 308 disposed above the touch control layer 307, and a cover plate 309 disposed above the polarizer 308. The OLED display panel provided by the present embodiment has same beneficial effects as the above-mentioned array substrate, which are not described again.

The description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

1. An array substrate, comprising:
a substrate;
a first thin-film transistor (TFT) disposed above the substrate and comprising a first active layer, a first gate, and a first source/drain electrode; and
a second TFT disposed above the substrate and comprising a second active layer, a second gate, and a second source/drain electrode;
wherein the first active layer and the second active layer are disposed on a same layer, a material of the first active layer and a material of the second active layer are different, the first gate and the second gate are disposed on a same layer, and the first source/drain electrode and the second source/drain electrode are disposed on a same layer.

2. The array substrate of claim 1, further comprising a shielding layer disposed above the substrate and disposed below the first TFT and the second TFT, and a buffer layer disposed above the substrate and covering the shielding layer, wherein the shielding layer is electrically connected to the first source/drain electrode or the second source/drain electrode by a first conductive pillar.

3. The array substrate of claim 2, wherein the substrate comprises a stacked layer comprising an organic layer and an inorganic layer.

4. The array substrate of claim 1, wherein the material of the first active layer is low-temperature polycrystalline silicon, and the material of the second active layer is an oxide.

5. The array substrate of claim 2, wherein the first TFT further comprises a first gate insulating layer disposed above the buffer layer, a second gate insulating layer disposed above the first gate insulating layer, and a third gate disposed above the second gate insulating layer.

6. The array substrate of claim 2, wherein the first source/drain electrode is connected to the second source/drain electrode, and the first conductive pillar is disposed at a connecting part between the first TFT and the second TFT.

7. The array substrate of claim 1, further comprising a passivation layer covering the first source/drain electrode and the second source/drain electrode, a planarization layer disposed above the passivation layer, and an anode layer and a pixel-defining layer disposed above the planarization layer, wherein the anode layer is electrically connected to the first source/drain electrode or the second source/drain electrode by a second conductive pillar.

8. A method of manufacturing an array substrate, comprising following steps:
providing a substrate;
forming a first thin-film transistor (TFT) comprising a first active layer, a first gate, and a first source/drain electrode above the substrate, and forming a second TFT comprising a second active layer, a second gate, and a second source/drain electrode above the substrate, wherein the first active layer and the second active layer are disposed on a same layer, a material of the first active layer and a material of the second active layer are different, the first gate and the second gate are formed by a single patterning process, and the first source/drain electrode and the second source/drain electrode are formed by a single patterning process.

9. The method of claim 8, further comprising following steps:
forming a shielding layer above the substrate and below the first TFT and the second TFT, wherein the shielding layer is electrically connected to the first source/drain electrode and/or the second source/drain electrode by a first conductive pillar; and
forming a buffer layer above the substrate and covering the shielding layer.

10. The method of claim 9, wherein the substrate comprises a stacked layer comprising an organic layer and an inorganic layer.

11. The method of claim 8, wherein the material of the first active layer is low-temperature polycrystalline silicon, and the material of the second active layer is an oxide.

12. The method of claim 9, wherein the first TFT further comprises a first gate insulating layer disposed above the buffer layer, a second gate insulating layer disposed above the first gate insulating layer, and a third gate disposed above the second gate insulating layer.

13. The method of claim 9, wherein the first source/drain electrode is connected to the second source/drain electrode, and the first conductive pillar is disposed at a connecting part between the first TFT and the second TFT.

14. The method of claim 8, wherein the array substrate further comprises a passivation layer covering the first source/drain electrode and the second source/drain electrode, a planarization layer disposed above the passivation layer, and an anode layer and a pixel-defining layer disposed above the planarization layer, and the anode layer is electrically connected to the first source/drain electrode or the second source/drain electrode by a second conductive pillar.

15. An organic light-emitting diode (OLED) display panel, comprising:
the array substrate of claim 1;
an organic light-emitting layer disposed above the array substrate;
a cathode layer disposed above the organic light-emitting layer;
a thin-film encapsulation layer disposed above the cathode layer;
a touch control layer disposed above the thin-film encapsulation layer;
a polarizer disposed above the touch control layer; and
a cover plate disposed above the polarizer.

16. The OLED display panel of claim 15, further comprising a shielding layer disposed above the substrate and disposed below the first TFT and the second TFT, and a buffer layer disposed above the substrate and covering the shielding layer, wherein the shielding layer is electrically connected to the first source/drain electrode or the second source/drain electrode by a first conductive pillar.

17. The OLED display panel of claim 16, wherein the substrate comprises a stacked layer comprising an organic layer and an inorganic layer.

18. The OLED display panel of claim 15, wherein the material of the first active layer is low-temperature polycrystalline silicon, and the material of the second active layer is an oxide.

19. The OLED display panel of claim 16, wherein the first TFT further comprises a first gate insulating layer disposed above the buffer layer, a second gate insulating layer disposed above the first gate insulating layer, and a third gate disposed above the second gate insulating layer.

20. The OLED display panel of claim 16, wherein the first source/drain electrode is connected to the second source/drain electrode, and the first conductive pillar is disposed at a connecting part between the first TFT and the second TFT.
